(19) United States
(12) Patent Application Publication
(10) Pub. No.: US 2026/0369858 A1
(43) Pub. Date: Nov. 19, 2026

(54) SMALL-FOOTPRINT INDUCTOR-BASED POWER DIVIDERS

(71) Applicant: EMTAR Technologies Inc., Richmond (CA)

(72) Inventors: Min-Yu HUANG, Richmond (CA); Navid HOSSEINI, Richmond (CA)

(73) Assignee: EMTAR Technologies Inc., Richmond (CA)

(21) Appl. No.: 19/727,552

(22) Filed: Jul. 1, 2026

Related U.S. Application Data
(63) Continuation of application No. PCT/IB2026/050916, filed on Jan. 30, 2026.
(60) Provisional application No. 63/752,584, filed on Jan. 31, 2025.

(51) Int. Cl. H01P 5/16; H03H 7/00

(52) U.S. Cl. CPC H01P 5/16; H03H 7/00

(57) ABSTRACT

The present disclosure provides various techniques for implementing compact, scalable, and broadband power divider/combiner circuits on an integrated circuit. In various embodiments, a T-junction-type or Gysel-type topology can be realized using lumped element resonator sections arranged as cascaded inductor-capacitor Pi networks that approximate a distributed transmission line response. Inductive conductors for multiple resonator sections can be arranged in a concentric polygonal footprint to reduce area and interconnect length while preserving symmetry between branches to support amplitude and phase balance. Scalability can be achieved through coplanar expansion of inductive conductors, or by vertical stacking of inductive conductors across metal layers, or both. The stacked inductors can be configured to share magnetic flux to increase effective inductance density. Some embodiments further include tunable capacitance elements that can enable reconfigurable operating frequency and bandwidth.

### CROSS REFERENCE TO RELATED APPLICATION

This application is a continuation of International Application No. PCT/IB2026/050916, filed Jan. 30, 2026, and entitled “SMALL-FOOTPRINT INDUCTOR-BASED POWER DIVIDERS,” which claims the benefit of U.S. Provisional Patent Application No. 63/752,584, filed Jan. 31, 2025, and entitled “ULTRA-COMPACT AND SCALABLE WIDEBAND POWER SPLITTER/COMBINER,” which are assigned to the assignee hereof. The disclosure of the prior Applications are considered part of and are incorporated by reference in this Patent Application.

### TECHNICAL FIELD

This present disclosure relates generally to electronic circuit design, and more specifically, to layout design for inductor-based power dividers (e.g., T-junction divider-type and Gysel-type) that use on-chip inductors and other passive components.

### BACKGROUND

Radio frequency (RF) systems and their applications including, e.g., sixth-generation (6G) and beyond telecommunications networks, Wi-Fi systems, satellite and non-terrestrial networks (NTN), integrated sensing and communication (ISAC), vehicle-to-everything (V2X) systems, Internet-of-Things (IoT) applications, industrial and private networks, defense and aerospace systems, and medical and wearable devices, have become an integral part of modern society.

Power divider and power combiner circuits are commonly used in RF and microwave systems to distribute signals among multiple signal paths or to combine signals from multiple sources. Conventional power divider designs, such as T-junction divider and Gysel power dividers, are typically implemented using quarter-wavelength transmission line sections to achieve impedance matching and port isolation. Although these transmission-line-based designs are useful, they can occupy relatively large physical areas, particularly when implemented on integrated circuits or when extended to multi-section configurations to support broadband operation. However, in integrated circuit environments, the area required for transmission lines presents a significant limitation. As additional resonator sections are added, transmission-line lengths increase, making such designs difficult to scale within area-constrained radio-frequency integrated circuits.

Lumped-element power divider implementations have been proposed to reduce circuit size by replacing transmission lines with inductors and capacitors. However, conventional lumped-element approaches typically rely on multiple discrete inductors, each occupying a separate footprint. As the number of resonator sections increases, overall layout area and routing complexity also increase. In addition, maintaining symmetry between signal paths becomes more challenging as component count grows, which can adversely affect amplitude and phase balance.

Power handling considerations further complicate existing designs. For example, although T-junction divider typically provide no output-port isolation and can exhibit degraded match under load mismatch, while Gysel power dividers use grounded isolation loads that add further circuit complexity and area. As a result, existing power divider architectures continue to face challenges related to footprint size, scalability, and suitability for highly integrated circuit implementations.

### BRIEF DESCRIPTION OF THE DRAWINGS

One or more embodiments of the present disclosure are illustrated by way of example and not limitation in the figures of the accompanying drawings, in which like references indicate similar elements. These drawings are not necessarily drawn to scale.

FIG. 1 shows a circuit schematic of an example T-junction power divider circuit.

FIG. 2A shows an example layout of an input-side portion of a T-junction type power divider circuit, including a corresponding circuit representation.

FIG. 2B shows an example layout of a resonator section that can be used as a building block in a T-junction power divider circuit, including a corresponding circuit representation.

FIG. 2C shows an example layout of a T-junction power divider circuit that combines the input-side portion of FIG. 2A with one or more resonator sections of FIG. 2B, including a corresponding circuit representation.

FIG. 3 shows an example layout of a T-junction power divider circuit implementing a coplanar expansion technique disclosed here for scalability.

FIG. 4 shows an example layout of a T-junction power divider circuit implementing a vertical stacking technique disclosed here for scalability.

FIG. 5 shows a circuit schematic of an example Gysel-type power divider circuit.

FIG. 6 shows a circuit schematic of a multi-section Gysel-type power divider circuit that is adapted to implement one or more of the techniques disclosed here for achieving a compact footprint.

FIG. 7 shows an example layout of the Gysel-type power divider circuit in which inductive conductors associated with multiple resonator sections are arranged in a compact footprint using a coplanar expansion technique.

FIG. 8A shows an example partial layout of a Gysel-type power divider circuit in which its isolation network is omitted.

FIG. 8B shows an example layout illustrating coplanar inductors arranged as cascaded inductor-capacitor (LC) Pi elements that implement at least a portion of an isolation network for the Gysel-type power divider of FIG. 8A.

FIG. 8C shows an example layout that combines the layouts of FIGS. 8A and 8B to implement a Gysel-type power divider circuit using a hybrid footprint that includes both coplanar inductors and vertically stacked inductors.

FIG. 9 shows in concept the reconfigurability of the proposed design using tunable capacitance elements, such as a switched capacitor bank package and/or one or more varactors.

### DETAILED DESCRIPTION

In modern radio frequency (RF) systems, power divider and power combiner circuits are commonly deployed as passive building blocks that distribute an input signal to multiple signal paths or combine signals from multiple sources. Such circuits are frequently used in front-end architectures that drive phased-array antennas, support multi-channel transceivers, or combine outputs of multiple power amplifiers, where compact integration and consistent signal distribution are often design considerations.

As described above, power divider and power combiner circuits are commonly implemented using transmission-line structures to provide impedance transformation, port matching, and isolation. In integrated circuit implementations, however, transmission lines typically consume substantial area, and extending a design to multiple sections to satisfy bandwidth or other requirements can further increase routing complexity and chip footprint. Lumped-element approaches have been used as alternatives to transmission-line implementations, but conventional implementations often rely on multiple discrete inductors and capacitors that each occupy a separate layout region. As additional resonator sections are added, the accumulated inductor footprint and interconnect routing can make it difficult to maintain symmetry between signal paths, which in turn can degrade amplitude and phase balance between output ports.

Introduced here, therefore, are techniques that can be used to implement a compact-footprint power divider circuit using resonator sections that are connected in cascade along a transmission branch and a coupling branch. In various embodiments, an inductor in a first resonator section of the transmission branch and a corresponding inductor in a first resonator section of the coupling branch can be implemented as polygonal or circular inductive conductors that are vertically stacked on different metal layers while occupying substantially the same inductor footprint when viewed in plan. In various embodiments, the inductive conductor shapes can be selected to be substantially complementary such that the stacked inductors together define a composite polygonal or circular pattern.

Overall, the embodiments of the present disclosure can reduce layout area and improve scalability by allowing additional resonator sections to be implemented through coplanar expansion and/or vertical stacking, rather than by replicating separate standalone inductors for each section. For example, coplanar expansion can extend inductive conductors laterally within a metal layer to form additional resonator sections, and vertical stacking can place inductive conductors on different metal layers to reuse planar footprint while providing magnetic flux sharing that increases effective inductance.

In addition, the same general resonator-section approach can be applied to different circuit architectures, including T-junction-type and Gysel-type configurations. In some embodiments, one or more resonator sections can include a tunable capacitor, such as a switched capacitor bank or a varactor, to adjust an operating frequency of the power divider circuit while preserving the resonator-section framework. It is further noted that the various techniques introduced in the present disclosure are described using power dividers as examples; however, the disclosed techniques are similarly applicable to power combiners as well.

In the following, numerous specific details are set forth to provide a thorough understanding of the presently disclosed techniques. In other embodiments, the techniques introduced here can be practiced without these specific details. In other instances, well-known features, such as specific fabrication techniques, are not described in detail in order to avoid unnecessarily obscuring the present disclosure. References in this description to “an embodiment,” “one embodiment,” or the like, mean that a particular feature, structure, material, or characteristic being described is included in at least one embodiment of the present disclosure. Thus, the appearances of such phrases in this specification do not necessarily all refer to the same embodiment. On the other hand, such references are not necessarily mutually exclusive either. Furthermore, the particular features, structures, materials, or characteristics can be combined in any suitable manner in one or more embodiments. Also, it is to be understood that the various embodiments shown in the figures are merely illustrative representations and are not necessarily drawn to scale.

Certain details relating to structures or processes commonly associated with the integrated circuit design, including physical layouts of typical passive components, e.g., inductors, capacitors, resistors, filters, and related subcomponents, may not be set forth in the following description, as inclusion of such well-known details could obscure significant aspects of the disclosed techniques. Moreover, although the following disclosure sets forth several embodiments of different aspects of the present disclosure, several other embodiments can have different configurations or different components than those described in this section. Accordingly, the introduced techniques can have other embodiments with additional elements or without several of the elements described below.

For purposes of discussion here, the terms “coupled” and “connected,” along with their derivatives, can be used to describe structural relationships between components. It should be understood that these terms are not intended as synonyms for each other. Rather, in particular embodiments, “connected” can be used to indicate that two or more elements are in direct contact with each other. Unless otherwise made apparent in the context, the term “coupled” can be used to indicate that two or more elements are in either direct or indirect (with other intervening elements between them) contact with each other, or that the two or more elements co-operate or interact with each other (e.g., as in a cause and effect relationship), or both. Notwithstanding the above, and unless otherwise specified or made clear by the context, references to components being “connected in series” or “connected in parallel” refer to their functional electrical relationship rather than requiring uninterrupted physical conductors.

For purposes of discussion here, the terms “plan view,” “viewed in plan,” “top view,” and “top plan view,” or wording to the equivalent, refer to a view of an integrated circuit layout projected onto a plane parallel to the surface of the semiconductor wafer, without regard to the vertical positions of elements on different metal layers. In such a view, elements disposed on different layers may appear to overlap or coincide, even though they can be physically separated in the vertical direction.

For purposes of discussion here, the terms “vertical” and “horizontal” are defined with respect to the surface of a semiconductor wafer on which an integrated circuit is fabricated. A vertical direction refers generally to a direction normal (perpendicular) to the plane of the wafer, while a horizontal direction refers generally to a direction parallel to the plane of the wafer.

For purposes of discussion here, the term “resonator” refers to a circuit element that exhibits a resonant impedance characteristic. A resonator can include an inductor, a capacitor, a resistor, or a suitable combination thereof.

For purposes of discussion here, the term “complementary in shape” refers to two or more geometric shapes that, when combined, overlapped, or arranged together (e.g., by vertical stacking and viewed in plan) collectively form a larger geometric pattern having an overall shape. The individual shapes need not be identical, symmetric, or continuous by themselves, and can include partial polygonal or circular segments, so long as their combined arrangement defines the intended composite shape.

For purposes of discussion here, the term “substantially the same inductor footprint” means that two or more inductors occupy largely overlapping planar regions (e.g., of an integrated circuit) and, when viewed in plan, even if the inductors are implemented on different metal layers, have different internal routing, or differ in minor geometric details. Inductors may be considered to occupy substantially the same footprint even if their outer boundaries are not perfectly coincident, provided that they are confined to a common footprint region.

For purposes of discussion here, the term “primarily,” when used to describe the disposition of a component on a particular layer or in a particular orientation, means that a larger portion of the component is disposed on that layer or in that orientation than on any other single metal layer or orientation, even if less than a majority of the component is so disposed.

For purposes of discussion here, “coplanar expansion” refers to implementing an inductor by extending an inductive conductor laterally within a same metal layer (or within a same set of metal layers without vertical stacking) in an X direction and/or a Y direction of the integrated circuit so as to increase inductive conductor length and/or to implement additional resonator sections.

For purposes of discussion here, “vertical stacking” refers to implementing inductive conductors on different metal layers and aligning at least a portion of those inductive conductors such that they overlap in plan view and occupy substantially a same planar footprint, while being separated by one or more interlayer dielectric regions.

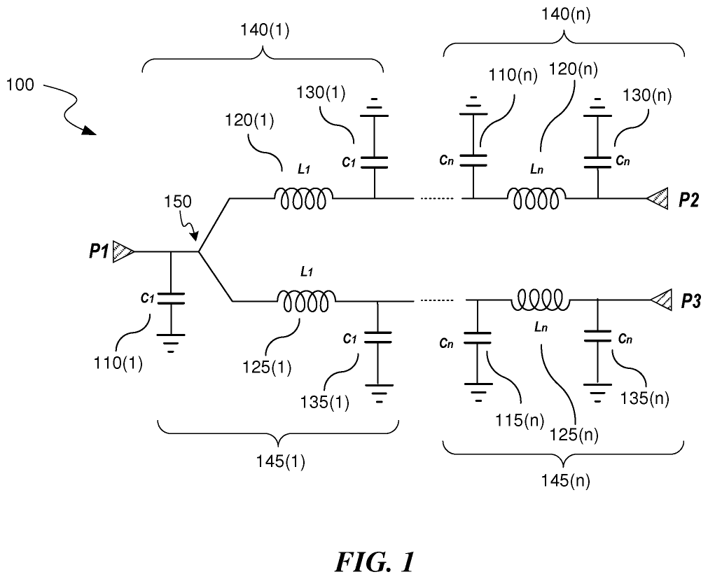

FIG. 1 shows a circuit schematic of an example T-junction power divider circuit 100. The power divider circuit 100 includes an input port P1, a transmitted port P2, and a coupled port P3. In the illustrated embodiment, an input signal received at the input port P1 is split at a power splitting junction 150 into a transmission branch (e.g., the upper branch in FIG. 1) and a coupling branch (e.g., lower branch in FIG. 1), and the transmission branch and the coupling branch can provide respective output signals at the transmitted port P2 and the coupled port P3.

In accordance with one or more embodiments, the transmission branch and the coupling branch each include a matching number of resonator sections connected in cascade. As shown in FIG. 1, the transmission branch can include one or more resonator sections 140(1) through 140(n), and the coupling branch can include one or more resonator sections 145(1) through 145(n). Each resonator section in the resonator sections 140(1)-140(n) of the transmission branch corresponds to a respective resonator section in the resonator section 145(1)-145(n) of the coupling branch. For example, the resonator section 140(1) in the transmission branch corresponds to the resonator section 145(1) in the coupling branch, the resonator section 140(2) in the transmission branch corresponds to the resonator section 145(2) in the coupling branch, and so forth. This configuration provides a symmetric circuit topology between the two branches. The number (n) can be selected based on a variety of suitable factors including, e.g., a target operating frequency range, bandwidth, matching, and isolation requirements.

In many conventional implementations, T-junction power divider networks are inherently narrowband. Accordingly, in various embodiments, broadband operation can be supported by extending the lumped-element implementation using multiple cascaded LC Pi sections. Specifically, in one or more embodiments, the resonator sections 140(1)-140(n) and 145(1)-145(n) can be implemented using lumped inductive and capacitive elements arranged as inductor-capacitor (LC) π networks (or “Pi networks”). For example, in the transmission branch, the resonator section 140(1) can include a series inductor 120(1) and a shunt capacitor 130(1). In the coupling branch, the resonator section 145(1) can include a series inductor 125(1) and a shunt capacitor 135(1). The shunt capacitor 110(1) can be coupled between an input-side node at the power splitting junction 150 and a reference potential (e.g., ground). Note that, in the illustrated embodiment, the shunt capacitor 110(1) is shared by the transmission branch and the coupling branch and forms part of an input-side network that is common to the cascaded resonator sections 140(1)-140(n) and 145(1)-145(n). In other words, the capacitor 110(1) can be viewed as the input-side shunt element associated with the first lumped Pi-section stage that feeds the cascaded resonator sections in each branch. However, other suitable circuitry configurations can be implemented.

In various embodiments, the cascaded inductors and shunt capacitors provide a lumped-element implementation that corresponds to a distributed-element transmission-line model. For example, like a distributed-element model that uses one or more transmission-line sections, different portions of the power divider circuit 100 can be implemented using cascaded series inductors and shunt capacitors arranged as resonator sections. In this manner, each resonator section 140(1)-140(n) and each resonator section 145(1)-145(n) can be designed as a respective LC Pi section that implements a portion of an impedance-transforming network along the corresponding branch.

Furthermore, in some embodiments of the present disclosure, additional resonator sections can be cascaded to extend the circuit. For example, in the transmission branch of the power divider circuit 100, an example later resonator section 140(n) includes a shunt capacitor 110(n), a series inductor 120(n), and a shunt capacitor 130(n). In a similar fashion, in the coupling branch of the power divider circuit 100, a corresponding resonator section 145(n) includes a shunt capacitor 115(n), a series inductor 125(n), and a shunt capacitor 135(n). Note that the circuit 100 is merely representative; in various implementations, one or more intermediate resonator sections can be included in the cascade between the first resonator sections and the n-th resonator sections. In various embodiments, the values of the inductors and capacitors can be selected so that the cascaded resonator sections collectively approximate impedance-transforming behavior typically associated with distributed transmission line sections, while remaining implementable as lumped elements on an integrated circuit. Accordingly, the lumped-element network can be extended using multiple cascaded LC Pi sections to support a target bandwidth and operating frequency range.

As practical application note, the T-junction power divider is a reactive-type structure that omits an isolation resistor. In general, T-junction dividers can provide relatively high power-handling capability, but can present a trade-off in output-port isolation and impedance matching, particularly under load mismatch conditions.

Note that, although FIG. 1 is described in the context of power division from the input port P1 to the transmitted port P2 and the coupled port P3, the same topology can be used for power combining by operating the circuit in the reverse direction, where signals applied at the transmitted port P2 and the coupled port P3 are combined at the input port P1. In addition, as is described in more detail below, while FIG. 1 illustrates the resonator sections using discrete inductors and capacitors for clarity, in various embodiments the inductors 120(1), 120(n), 125(1), and 125(n) and the capacitors 110(1), 110(n), 115(n), 130(1), 130(n), 135(1), and 135(n) can be implemented using integrated passive structures on one or more metal layers of an integrated circuit, with the corresponding structures in the transmission branch and the coupling branch laid out in a symmetric manner to support matched signal paths.

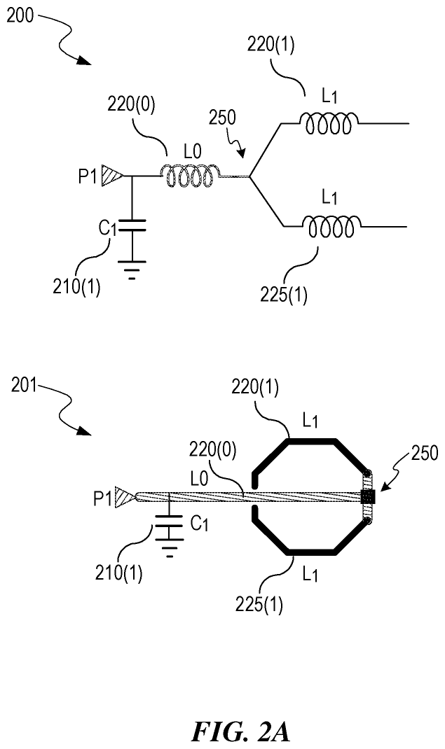

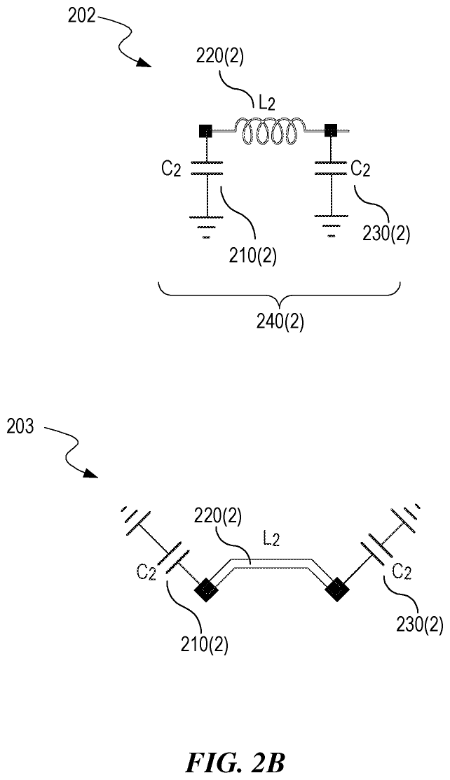

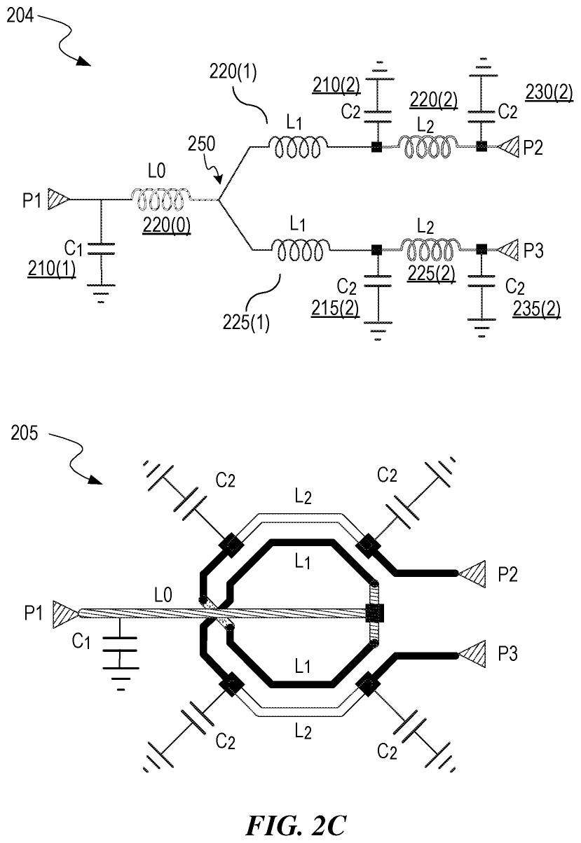

FIG. 2A shows an example layout 201 of an input-side portion of a T-junction power divider circuit, including a corresponding circuit representation 200. In the circuit representation 200, an input port P1 is coupled to a shunt capacitor 210(1) referenced to a reference potential. The input port P1 is also coupled through a series inductor 220(0) to a power splitting junction 250. From the power splitting junction 250, the circuit splits into a transmission branch and a coupling branch. In the illustrated embodiment, the transmission branch includes a series inductor 220(1), and the coupling branch includes a series inductor 225(1). In various embodiments, the shunt capacitor 210(1) and the series inductor 220(0) can form an input-side matching and filtering network that cooperates with subsequent resonator sections, thereby supporting a target port impedance and a desired input return loss over a target operating band.

The layout 201 illustrates one example integrated implementation of the input-side portion of the power divider circuit. A conductive input trace routes an input signal from the input port P1 to the power splitting junction 250. In the illustrated embodiment, the series inductor 220(0) is implemented along the input trace as an inductive conductor segment that provides the inductance L0. The shunt capacitor 210(1) is coupled between the input-side node associated with the input port P1 and the reference potential.

In some embodiments, the shunt capacitor 210(1) can be implemented as a pad capacitor at the input port P1, and the series inductor 220(0) can be implemented as an input inductor that provides a transmission-line-equivalent connection from the input port P1 to the power splitting junction 250. In FIG. 2A, the conductive trace implementing the series inductor 220(0) is shown to demonstrate an example input-side metal layer conductor routing from the input port P1 to the power splitting junction 250.

Furthermore, the power splitting junction 250 can be implemented as a branching node that divides the conductive input trace into two paths that can be laid out in a symmetric manner. In one or more embodiments, the series inductor 220(1) associated with the transmission branch and the series inductor 225(1) associated with the coupling branch can be implemented using polygonal inductive conductor segments that together define a polygonal loop around a shared region of layout area. In some embodiments, the power splitting junction 250 can be implemented using a conductive interconnect region, and the coupling from the input trace to the branch inductors can be made through one or more interconnect features, e.g., a via or a via region at or near the power splitting junction 250. This arrangement can provide a compact connection between the input inductor and the branch inductors while preserving symmetry between the two branch paths.

It is noted in the present disclosure that maintaining symmetry in the physical implementation of the series inductor 220(1) and the series inductor 225(1) can reduce branch-to-branch differences in parasitic resistance and parasitic capacitance, and can reduce branch-to-branch differences in parasitic coupling attributable to layout asymmetries. As a result, the input-side portion 200 can support improved amplitude and phase balance between the two branches when the T-junction power divider circuit is extended with additional resonator sections. In addition, placing the series inductor 220(1) and the series inductor 225(1) adjacent to the power splitting junction 250 can reduce interconnect length between the splitting node and later resonator sections, which can reduce routing-induced parasitics and improve predictability of the intended lumped-element values.

FIG. 2B shows an example layout 203 of a resonator section 240(2) that can be used as a building block in a T-junction power divider circuit, along with a corresponding circuit representation 202. In one or more embodiments, multiple resonator sections of the type shown in FIG. 2B can be connected in cascade in each of a transmission branch and a coupling branch (e.g., as described above with respect to FIG. 1), thereby enabling a multi-section lumped-element implementation that corresponds to a distributed-element transmission-line model.

In the circuit representation 202, the resonator section 240(2) includes a series inductor 220(2) coupled between a first node and a second node. The first node is coupled to a shunt capacitor 210(2) referenced to a reference potential, and the second node is coupled to a shunt capacitor 230(2) referenced to the reference potential. Note that, at least in some embodiments here, a suitable reference potential can be implemented as ground, zero volt, or another reference node (e.g., an analog ground node, or a common-mode bias node). According to the present disclosure, the resonator section 240(2) can implement an LC Pi network in which the series inductor 220(2) is positioned between two shunt capacitors 210(2) and 230(2). In various embodiments, the values of the series inductor 220(2) and the shunt capacitors 210(2) and 230(2) can be selected so that the resonator section 240(2) provides a desired impedance-transforming behavior over a target operating frequency range.

The layout 203 illustrates one example integrated circuit implementation of the resonator section 240(2). As shown in FIG. 2B, the series inductor 220(2) can be implemented as a conductive trace segment that provides the inductance L2. The endpoints of the conductive trace segment correspond to the first node and the second node of the circuit representation 202. At each endpoint, a respective shunt capacitor 210(2) or 230(2) is coupled from the node to the reference potential. In various embodiments, the shunt capacitors 210(2) and 230(2) can be implemented using integrated capacitive structures (e.g., metal-insulator-metal capacitors, metal-oxide-semiconductor capacitors, or other suitable integrated capacitors) that are coupled between the node and the reference potential.

According to a number of embodiments, the resonator section 240(2) can provide a modular unit cell that can be replicated to increase a number of cascaded sections in a branch. This modularity can provide practical scalability because additional sections can be added by repeating the same general topology and layout motif, and corresponding resonator sections in the transmission branch and the coupling branch can be placed using mirrored or otherwise symmetric geometry.

FIG. 2C shows an example T-junction power divider circuit 204 and a corresponding layout 205 in which the input-side portion of FIG. 2A is combined with one or more resonator sections of FIG. 2B. In one or more embodiments, the T-junction power divider circuit 204 can represent a multi-section implementation in which a first stage includes an input-side network and branch inductors 220(1) and 225(1), and a second stage includes a resonator section in each branch implemented as an LC Pi network. As shown in the circuit representation 204, the input-side network can include an input port P1 that is coupled to a shunt capacitor 210(1) and to a series inductor 220(0). In one or more embodiments, the series inductor 220(0) couples the input port P1 to a power splitting junction 250 that divides the circuit into a transmission branch and a coupling branch.

More specifically, the transmission branch can include a resonator section implemented as an LC Pi network that includes a series inductor 220(2) and two shunt capacitors 210(2) and 230(2). Similarly, the coupling branch can include a corresponding resonator section implemented as an LC Pi network that includes a series inductor 225(2) and two shunt capacitors 215(2) and 235(2). In the illustrated embodiment, the series inductor 220(2) is coupled between a first node and a second node, the shunt capacitor 210(2) is coupled between the first node and a reference potential, and the shunt capacitor 230(2) is coupled between the second node and the reference potential. In a similar fashion, the series inductor 225(2) is coupled between a first node and a second node, the shunt capacitor 215(2) is coupled between the first node and the reference potential, and the shunt capacitor 235(2) is coupled between the second node and the reference potential. In various embodiments, the LC Pi networks in the two branches can be configured to be electrically symmetric, which can support amplitude and phase balance between the transmitted port P2 and the coupled port P3 over a target operating band. This multi-section approach can extend a lumped-element model beyond a single-stage T-junction divider implementation, thereby supporting a wider operating bandwidth while maintaining a compact integrated implementation.

Moreover, because the LC Pi networks are modular, additional resonator sections can be added in cascade in each branch to further shape the impedance-transforming response while preserving the overall symmetric topology. Note that, in some embodiments, the series inductor 220(1) and the series inductor 225(1), together with cascaded LC Pi sections (e.g., including the series inductor 220(2), the series inductor 225(2), and the shunt capacitors 210(2), 215(2), 230(2), and 235(2)), can be selected such that the transmission branch and the coupling branch collectively approximate a quarter-wavelength-equivalent impedance transformation between the power splitting junction 250 and the output-side ports P2 and P3.

The T-junction power divider circuit 204 has no further isolation resistance between the output-side nodes associated with the transmitted port P2 and the coupled port P3.

As shown in FIG. 2C, the layout 205 illustrates an example integrated circuit implementation of the circuit 204 where inductive conductors are arranged in a nested polygonal configuration to reduce overall footprint. In one or more embodiments, the conductive routing from the input port P1 implements the series inductor 220(0) and is coupled to an interior interconnect region that forms the power splitting junction 250. The interior interconnect region is arranged such that it can distribute the input signal into two branch paths that implement the transmission branch and the coupling branch in a symmetric manner.

More specifically, in the layout 205, inductive conductor segments implementing the series inductor 220(1) and the series inductor 225(1) are arranged to define a first polygonal loop. Further in the layout 205, inductive conductor segments implementing the series inductor 220(2) and the series inductor 225(2) are arranged to define a second polygonal loop positioned around the first polygonal loop. In various embodiments, this nested, concentric arrangement can reduce the overall area relative to implementations that place the series inductors as separate standalone inductors. In addition, the nested arrangement can reduce the interconnect length between inductive elements of successive sections, which can in turn reduce the series resistance and routing-associated parasitic capacitance, thereby improving the predictability of intended lumped-element values.

The layout 205 also includes capacitor structures coupled between selected nodes and a reference potential (e.g., ground) to implement the shunt capacitors 210(1), 210(2), 215(2), 230(2), and 235(2). In various embodiments, implementing corresponding elements of the transmission branch and the coupling branch using substantially mirrored or otherwise symmetric placement and routing can reduce branch-to-branch parasitic mismatch and can support amplitude and phase balance between the output signals at the transmitted port P2 and the coupled port P3.

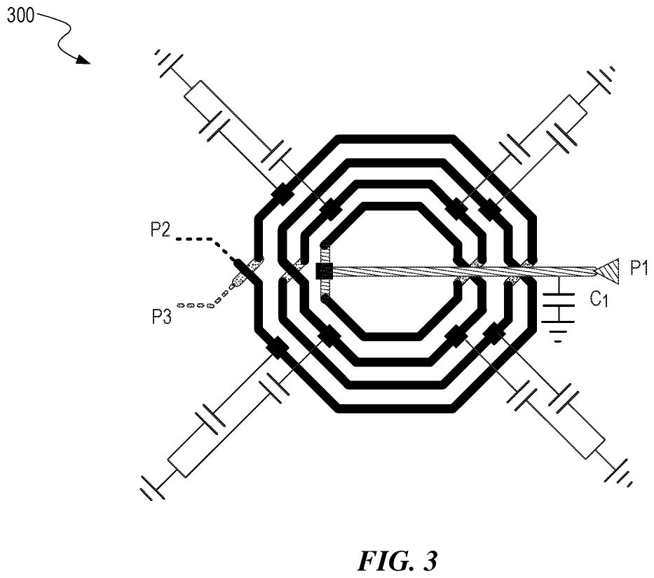

FIG. 3 shows an example layout 300 of a T-junction power divider circuit implementing a coplanar expansion technique for scalability. The layout 300 can correspond to a lumped-element T-junction implementation in which a transmission branch and a coupling branch include cascaded resonator sections (e.g., LC Pi sections) that approximate a distributed transmission-line response. Although FIG. 3 is described using power division as an example, the same topology can be used for power combining by operating the circuit in the reverse direction. Further, the lumped-element implementation can be configured with multiple resonator sections to support broadband operation over a target operating frequency range.

More specifically, as shown in FIG. 3, the layout 300 includes conductive routing coupled to the port P1 and configured to route an input signal to an interior interconnect region that feeds the remainder of the network. A shunt capacitor C1 is coupled to an input node associated with the conductive routing. In some embodiments, the shunt capacitor C1 can be implemented as, e.g., a pad capacitor or an integrated capacitor coupled between the input node and a reference potential (e.g., ground).

The layout 300 can further include inductive conductors arranged in a plurality of polygonal loops that are positioned concentrically. In the illustrated embodiment, the polygonal loops are implemented in a coplanar manner (e.g., primarily within the same metal layer or within the same set of metal layers without vertical stacking) such that additional resonator sections can be added by expanding the inductive conductor pattern laterally in an X direction and/or a Y direction of the integrated circuit. For example, a first polygonal loop can implement inductive conductors for a first resonator section, and one or more additional polygonal loops arranged around the first polygonal loop can implement inductive conductors for additional resonator sections. This coplanar expansion technique can enable the number of cascaded resonator sections to be increased while preserving a compact overall footprint, because the added inductive conductor length can be realized by outward growth of the polygonal pattern rather than by placing separate standalone inductors in distant locations. In some embodiments, the coplanar expansion can be implemented by outstretching a core inductor footprint and cascading additional inductive segments having, e.g., half-octagonal shapes, after which shunt branches are added to form the associated Pi sections.

In some embodiments, the series inductive conductors for the Pi-extension are laid out first in a cascaded manner, and shunt capacitor branches are then integrated into the layout at selected nodes to complete the LC Pi sections. It is noted in the present disclosure that implementing the proposed lumped-element circuit within a single compact inductor footprint can be desirable. The embodiment having concentric and laterally expanded arrangement in FIG. 3 can achieve compact inductor footprint by allowing multiple resonator sections to be integrated into a unified planar footprint while maintaining short interconnect distances between successive sections.

In addition, the layout 300 can maintain symmetry between the transmission branch and the coupling branch by implementing corresponding inductive conductor segments using mirrored or otherwise symmetric geometry about a central axis of the layout. As discussed above, maintaining such symmetry can reduce branch-to-branch variation in parasitic resistance and parasitic capacitance and can reduce branch-to-branch differences in parasitic coupling attributable to asymmetric routing. As a result, the coplanar expansion technique disclosed here can support amplitude and phase balance between the signals at the output-side ports P2 and P3 when the network is scaled to include additional resonator sections. In some embodiments, each pair of corresponding inductors in the transmission branch and the coupling branch is symmetric in shape when viewed in plan.

The layout 300 also illustrates an output-side interconnect region that couples to the ports P2 and P3. In a number of embodiments, output-side routing to the ports P2 and P3 can be implemented in a symmetric manner, which further supports matched electrical behavior between the two output paths as additional resonator sections are added through coplanar expansion.

Overall, FIG. 3 illustrates how the techniques of coplanar expansion of polygonal inductive conductor patterns can be used to scale a T-junction power divider circuit to include multiple cascaded resonator sections while maintaining a compact footprint and preserving branch symmetry. This approach can reduce routing length between successive sections and can reduce routing-induced parasitics, thereby improving predictability of intended lumped-element values and supporting consistent performance across a target operating frequency range.

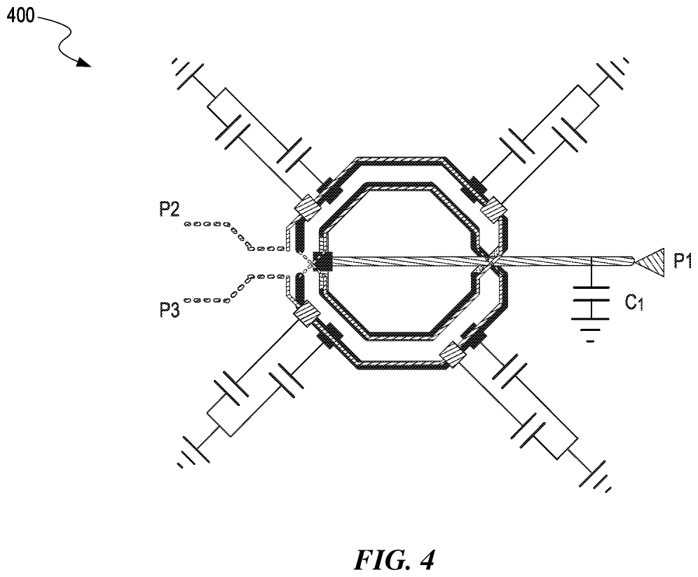

FIG. 4 shows an example layout 400 of a T-junction power divider circuit implementing a vertical stacking technique for scalability. In one or more embodiments, the layout 400 can implement a lumped-element T-junction network in which a transmission branch and a coupling branch include cascaded resonator sections (e.g., LC Pi sections) that approximate a distributed transmission-line response.

Similar to the layout 300 (in FIG. 3), the layout 400 includes an input port P1, output-side ports P2 and P3. Also similar to the layout 300 discussed above, the layout 400 includes conductive routing coupled to the input port P1 and configured to route an input signal to an interior interconnect region that feeds the remainder of the network. A shunt capacitor C1 is coupled to an input-side node associated with the input port P1. The shunt capacitor C1 can be implemented as a pad capacitor and/or an integrated capacitor coupled between the input-side node and a reference potential. In one or more embodiments, the interior interconnect region can implement a coupling node that distributes the input signal to the transmission branch and the coupling branch using symmetric routing, which can reduce branch-to-branch mismatch attributable to layout asymmetries.

In contrast to the coplanar scalability approach described above with respect to FIG. 3, FIG. 4 illustrates that scalability can be achieved by vertical stacking of inductive conductors across multiple metal layers of an integrated circuit. Specifically, in one or more embodiments, an inductor used in a resonator section can be implemented as two or more inductive conductors disposed on different metal layers and vertically aligned such that the inductive conductors occupy substantially the same planar footprint when viewed in plan. The inductive conductors can be coupled using one or more vias or via regions. This vertical stacking can increase inductance density because multiple inductive conductors can be placed within the same footprint that would otherwise be occupied by a single coplanar inductor.

It is observed in various present embodiments that vertically stacked inductive conductors can be arranged to share magnetic flux so as to increase an effective inductance relative to a non-stacked implementation. For example, a first inductive conductor can be primarily disposed on a first metal layer, and a second inductive conductor can be primarily disposed on a second metal layer different from the first metal layer, where the first inductive conductor and the second inductive conductor are vertically stacked and magnetically coupled. This magnetic coupling can enable a desired inductance value to be achieved with reduced planar area, which in turn can support a smaller overall layout footprint for a multi-section T-junction network.

In one or more embodiments, the vertical stacking technique can be applied to corresponding inductors in different branches of the T-junction power divider circuit. For example, an inductor in a first resonator section of the transmission branch can be primarily disposed on a first metal layer, while a corresponding inductor in a first resonator section of the coupling branch can be primarily disposed on a second metal layer different from the first metal layer. In such embodiments, the corresponding inductors can be vertically aligned and occupy substantially the same planar footprint when viewed in plan, while remaining electrically distinct portions of their respective branches. By stacking corresponding inductors of different branches in this manner, the layout 400 can reduce overall area while maintaining branch symmetry, thereby supporting amplitude and phase balance between signals at the output-side ports P2 and P3.

Further, in some embodiments, cascading additional inductors for the Pi-extension can be implemented by routing selected inductive conductors to one or more lower metal layers through vias, thereby forming stacked inductors for one or more additional resonator sections within substantially the same planar footprint. After the cascaded inductive conductors are formed across the stacked layers, shunt branches can be added to integrate the shunt capacitor sections at selected nodes, in a manner similar to the coplanar approach. In a number of implementations, mutual coupling among inductors can be managed by selecting the metal layers used for different inductors and by selecting which inductors are vertically aligned, thereby controlling magnetic coupling and supporting a target inductance profile and branch-to-branch matching. For example, a coupling coefficient among inductors can be tuned by selecting an ordering/assignment of metal layers used for the inductive conductors and by selecting via-coupling locations along the polygonal path.

In one or more embodiments, the vertically stacked inductive conductors can be implemented using complementary polygonal or circular shapes to improve layout compactness and symmetry. For example, a first inductive conductor can have a shape that is partially polygonal or circular, and a second inductive conductor can have a shape that is partially polygonal or circular and substantially complementary to the shape of the first inductive conductor. When the first inductive conductor and the second inductive conductor are vertically stacked and viewed in plan, the complementary shapes can together define a composite inductive conductor pattern that is substantially a complete polygonal or circular shape (e.g., a hexagon, an octagon, or a circle). In some embodiments, the complementary inductive conductors can be implemented to be symmetric with respect to one another about an axis (e.g., mirrored about a symmetry axis), which can reduce imbalance between the transmission branch and the coupling branch attributable to asymmetric parasitic effects. Additionally, in some embodiments, the complementary inductive conductors can be implemented to be rotationally symmetric with respect to one another (e.g., symmetric under rotation about a center point by a defined angle), which can likewise reduce such imbalance.

In the illustrated embodiment of FIG. 4, the layout includes inductive conductor portions implemented on different metal layers and one or more interconnect features (e.g., via regions at selected locations around a polygonal pattern) that electrically couple conductive features of different metal layers at selected nodes. In various embodiments, such interconnect features can electrically couple stacked conductors within a given inductor structure and/or can provide coupling at selected nodes to preserve the intended resonator network topology while supporting compact implementation.

In addition, in some embodiments, a power divider circuit can implement a hybrid inductive structure that includes both coplanar expanded inductors and vertically stacked inductors. For example, a first subset of resonator sections in each of the transmission branch and the coupling branch can be implemented using coplanar expansion as described above with respect to FIG. 3, while a second subset of resonator sections in each of the transmission branch and the coupling branch can be implemented using vertical stacking as described with respect to FIG. 4. In some hybrid implementations, a first resonator section can use corresponding inductors in the two branches that are vertically stacked on different metal layers, while one or more subsequent resonator sections can be implemented as one or more additional polygonal loops that are concentric with the first loop within the same footprint region. In this manner, the power divider circuit can be scaled using a combination of coplanar expansion and vertical stacking while preserving branch symmetry and compact layout.

It is noted that, in certain embodiments, vertically stacked inductive conductors can provide a more symmetric magnetic-flux distribution and higher inductor quality factor (and lower loss) than a purely coplanar concentric-ring implementation in which inner and outer rings can experience different flux distributions and additional dissipation due to intervening metal features. However, it is recognized in the present disclosure that one technique (e.g., vertical stacking) may not be always preferable over the other (e.g., coplanar expansion). As such, in various implementations, whether coplanar expansion, vertical stacking, or a hybrid of both is used can be selected based on an available metallization stack (e.g., a number of usable metal layers) and a layout-area budget for the integrated circuit.

Lastly, the layout 400 further includes output-side routing to the output-side ports P2 and P3. By combining output-port with footprint-efficient inductive structures implemented using vertical stacking (and, in some embodiments, combined with coplanar expansion), the layout 400 can support a compact, scalable T-junction power divider circuit suitable for integrated applications.

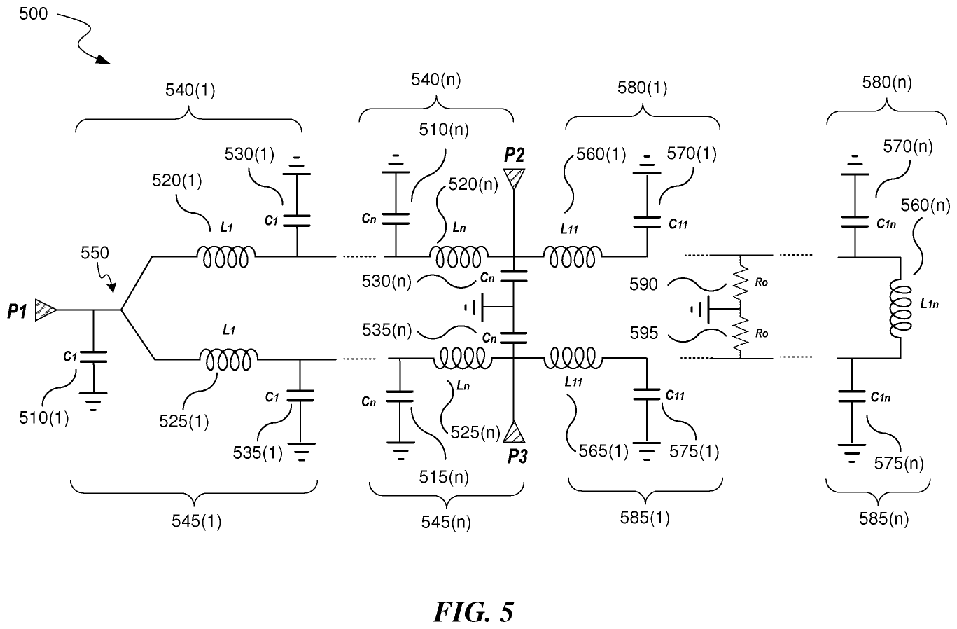

FIG. 5 shows a circuit schematic of an example Gysel-type power divider circuit 500. The power divider circuit 500 includes an input port P1, a transmitted port P2, and a coupled port P3. In the illustrated embodiment, an input signal received at the input port P1 is split at a power splitting junction 550 into a transmission branch (e.g., the upper branch in FIG. 5) and a coupling branch (e.g., the lower branch in FIG. 5), and the transmission branch and the coupling branch can provide respective output signals at the transmitted port P2 and the coupled port P3. Although FIG. 5 is described using power division as an example, the same topology can be used for power combining by operating the circuit in the reverse direction, where signals applied at the ports P2 and P3 are combined at the port P1.

In one or more embodiments, each of the transmission branch and the coupling branch includes a matching number of resonator sections connected in cascade. For example, the transmission branch can include one or more resonator sections 540(1) through 540(n), and the coupling branch can include one or more resonator sections 545(1) through 545(n). Each resonator section in the resonator sections 540(1)-540(n) of the transmission branch can correspond to a respective resonator section in the resonator sections 545(1)-545(n) of the coupling branch, thereby providing a symmetric circuit topology between the two branches. The number of stages (n) can be selected based on a variety of suitable factors including, e.g., a target operating frequency range, bandwidth, matching, and isolation requirements.

In various embodiments, the resonator sections 540(1)-540(n) and 545(1)-545(n) can be implemented using lumped inductive and capacitive elements arranged as LC Pi networks. For example, resonator section 540(1) can include a series inductor 520(1) and one or more shunt capacitors 510(1), 530(1) referenced to a reference potential (e.g., ground), and resonator section 545(1) can include a corresponding series inductor 525(1) and one or more shunt capacitors 510(1), 535(1) referenced to the reference potential. In a similar fashion, a later resonator section 540(n) can include a series inductor 520(n) and shunt capacitors 510(n), 530(n), and a corresponding resonator section 545(n) can include a series inductor 525(n) and shunt capacitors 515(n), 535(n). Note that the circuit 500 is merely representative; in various implementations, one or more intermediate resonator sections can be included in the cascade. This multi-section approach can extend a lumped-element implementation beyond a single-stage divider, thereby supporting broadband operation over a target operating frequency range while maintaining an integrated, compact implementation.

In one or more embodiments, the cascaded series inductors and shunt capacitors provide a lumped-element implementation that corresponds to a distributed-element transmission-line model. For example, like a distributed-element model that uses one or more transmission-line sections, different portions of the power divider circuit 500 can be implemented using cascaded series inductors and shunt capacitors arranged as resonator sections. In this manner, each resonator section can be designed as a respective LC Pi section that implements a portion of an impedance-transforming network along the corresponding branch, and the overall cascade can approximate impedance-transforming behavior typically associated with distributed transmission-line sections while remaining implementable as lumped elements on an integrated circuit.

Further, as shown in FIG. 5, the Gysel-type topology can provide isolation using isolation loads referenced to a reference potential rather than using an internal isolation resistor between the output ports. For example, the power divider circuit 500 can include isolation loads 590 and 595 (each having a resistance of approximately Ro) coupled to a reference potential and coupled to the network through the structures shown between the branches. In various embodiments, the isolation loads 590 and 595 are arranged so that imbalance power is routed away from the signal-carrying paths between the input port P1 and the output ports P2 and P3, thereby providing isolation between the output-side ports while reducing direct resistive loading between P2 and P3. For example, when the output signals are not equal in amplitude and phase, the isolation network can direct the corresponding imbalance energy toward the isolation loads 590 and 595, which can dissipate that energy while supporting stable divider behavior under mismatch conditions.

In various embodiments, the values of the inductors and capacitors in the resonator sections (e.g., the inductors labeled L1 and Ln, and the shunt capacitors labeled C1 and Cn) and the values/placement of the isolation loads (e.g., Ro) can be selected so that the cascaded resonator sections collectively support a target bandwidth, matching profile, and isolation performance. Further, because the resonator sections are modular, additional sections can be cascaded in each branch to scale the circuit response (e.g., to achieve a desired broadband impedance-transforming behavior) while preserving symmetry between the transmission branch and the coupling branch.

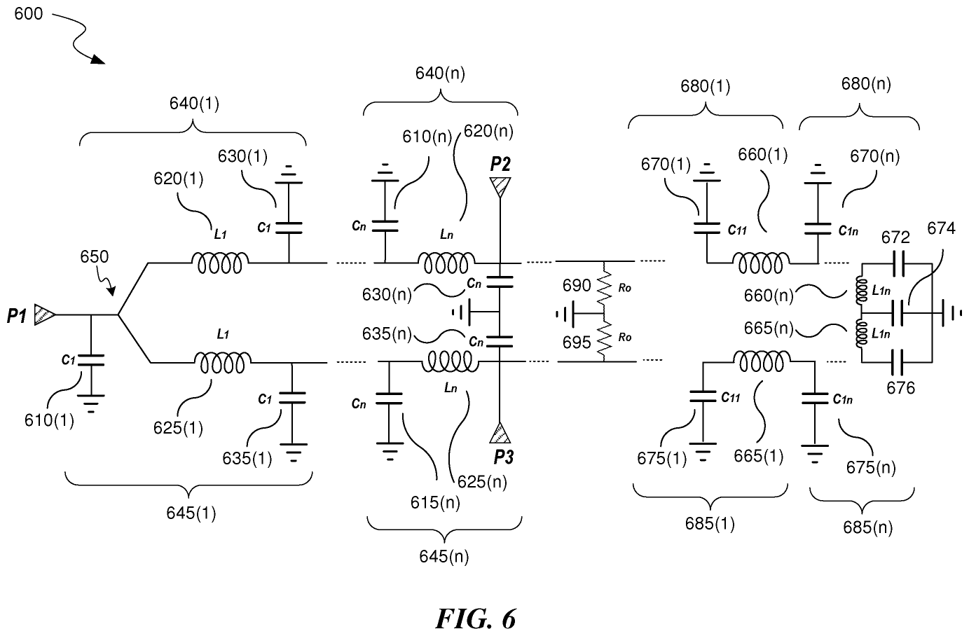

FIG. 6 shows a circuit schematic of a multi-section Gysel-type power divider circuit 600 that is adapted to implement one or more of the techniques disclosed here for achieving a compact footprint. The power divider circuit 600 includes an input port P1, output-side ports P2 and P3, and a power splitting junction 650 that splits an input signal into a transmission branch and a coupling branch, and the circuit can also be operated in reverse for power combining.

As compared to the example Gysel-type power divider circuit 500 of FIG. 5, the circuit 600 in FIG. 6 shows a multi-section implementation in which the isolation functionality can be realized using a more explicitly defined isolation-side network that can be frequency shaped. As shown in FIG. 6, the transmission branch includes cascaded resonator sections 640(1) through 640(n), and the coupling branch includes corresponding cascaded resonator sections 645(1) through 645(n), where corresponding resonator sections in the two branches can be selected to be electrically symmetric. Each resonator section can be implemented using lumped inductive and capacitive elements arranged as LC Pi networks, thereby extending a lumped-element implementation to approximate a distributed transmission-line response while remaining implementable in an integrated format.

Further, FIG. 6 illustrates that the isolation side includes one or more additional resonator sections 680(1) through 680(n) coupled to isolation loads 690 and 695 referenced to a reference potential. In various embodiments, the isolation-side resonator sections 680(1)-680(n) include inductive elements (e.g., inductors 660(1)-660(n) and 665(1)-665(n)) and capacitive elements (e.g., capacitors 670(1), 675(1), 670(n), and 675(n)) arranged to form a frequency dependent isolation path that can route imbalance energy to the isolation loads 690 and 695 while reducing direct resistive loading between the output-side ports P2 and P3.

Moreover, the circuit 600 includes an example termination network coupled toward a distal end of the isolation side. In the illustrated embodiment, the termination network includes inductive elements (e.g., inductors 660(n) and 665(n)) and capacitive elements 672, 674, and 676. In one or more embodiments, the termination network cooperates with the isolation-side resonator sections 680(1)-680(n) to establish a desired termination condition for the isolation side over a target operating frequency range, which can aid in controlling how imbalance energy is presented to and dissipated by the isolation loads 690 and 695.

Accordingly, while the circuit 600 shares with the circuit 500 the core Gysel-type concept of using isolation loads referenced to a reference potential, the circuit 600 provides an example in which the isolation side can be implemented as a multi-section resonator network with an explicit distal termination. This added structure can provide additional degrees of freedom for selecting impedance transformation and isolation behavior over frequency while preserving symmetry between the transmission branch and the coupling branch and maintaining a compact implementation suitable for integrated applications. It is also noted that, when compared to circuit 500, the circuit 600 in FIG. 6 is more distributed and can provide additional flexibility for layout purposes.

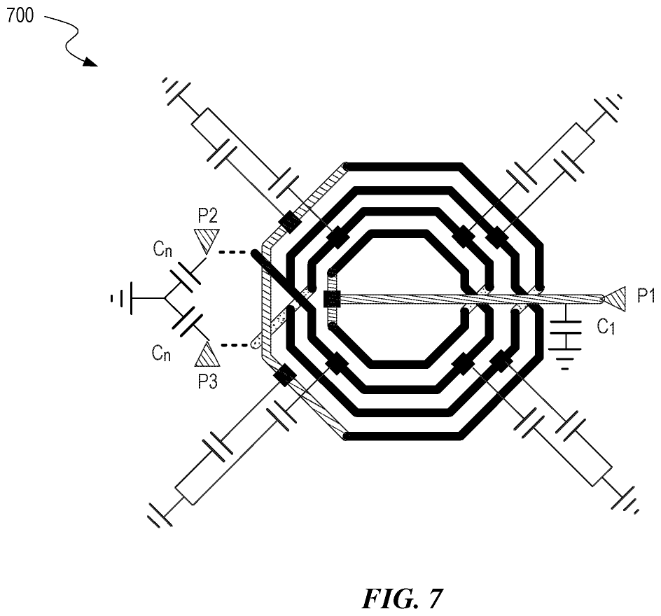

FIG. 7 shows an example layout 700 of the Gysel-type power divider circuit in which inductive conductors associated with multiple resonator sections are arranged in a compact footprint using a coplanar expansion technique. The layout 700 includes an input port P1 and output-side ports P2 and P3. In operation, a signal received at the input port P1 is distributed into a transmission branch and a coupling branch that respectively provide output signals at the ports P2 and P3. However, it is noted that the same topology can be used for power combining by operating the circuit in the reverse direction.

As shown in FIG. 7, the transmission branch and the coupling branch each can include a plurality of resonator sections connected in cascade to implement an impedance-transforming network along each branch. In one or more embodiments, the resonator sections can be implemented using inductive conductors arranged as concentric polygonal loops that share a common footprint region, rather than being implemented as separate standalone inductors placed in different regions of the integrated circuit. As discussed previously, this concentric arrangement can reduce routing length between successive resonator sections, which can in turn reduce routing-associated series resistance and parasitic capacitance and can improve correspondence between intended lumped-element values and realized electromagnetic behavior.

More specifically, in the layout 700, coplanar expansion can be realized by adding one or more outward polygonal loops around a core polygonal loop, such that each added loop contributes inductive conductor segments for one or more additional resonator sections while maintaining a compact overall footprint. This approach can support practical scalability because the number of cascaded sections can be increased to meet target bandwidth and matching requirements without requiring a proportional increase in die area.

FIG. 7 further illustrates that the Gysel-type topology can provide output isolation using isolation loads referenced to a reference potential, rather than using an internal isolation resistor coupled directly between the output-side ports. In one or more embodiments, the isolation network is arranged so that imbalance power is routed away from the signal-carrying paths between the input port P1 and the output-side ports P2 and P3 and is dissipated by the isolation loads. In the embodiment illustrated in the layout 700, conductive features associated with an isolation-load network are extended toward a peripheral region of the concentric polygonal footprint (e.g., along one or more outer polygonal rings), while conductive features associated with the main signal-carrying sections between the input port and the output-side ports (that are shown in the circuit schematic 600) are disposed more centrally (e.g., along one or more inner polygonal rings). Note that, for simplicity, the grounded resistors are excluded from the layout 700. It is also noted here that implementing the isolation-related impedance-transforming network using the same coplanar-expanded, compact footprint techniques described above can reduce area while preserving electrical symmetry.

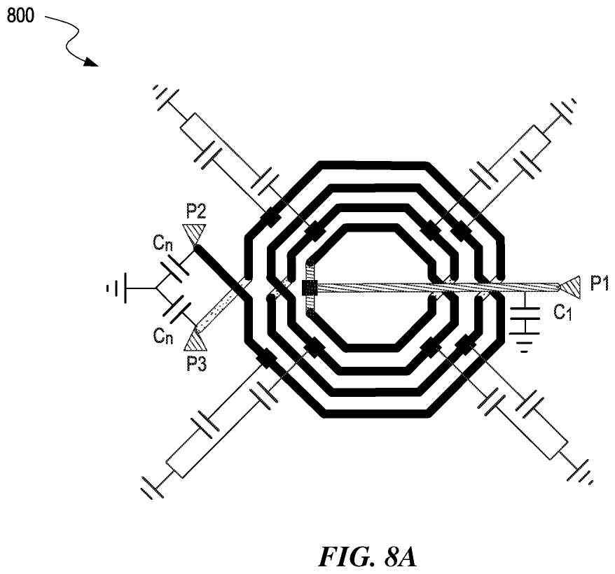

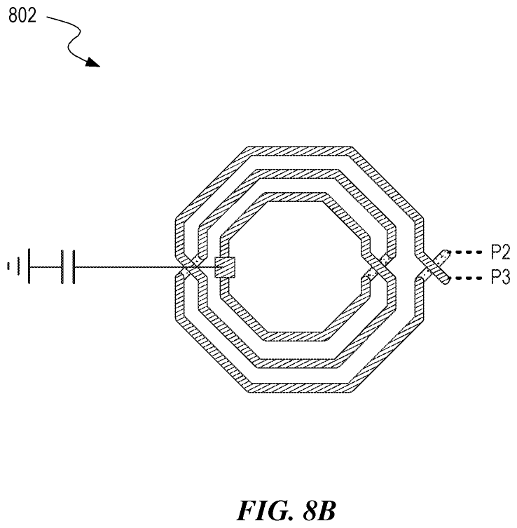

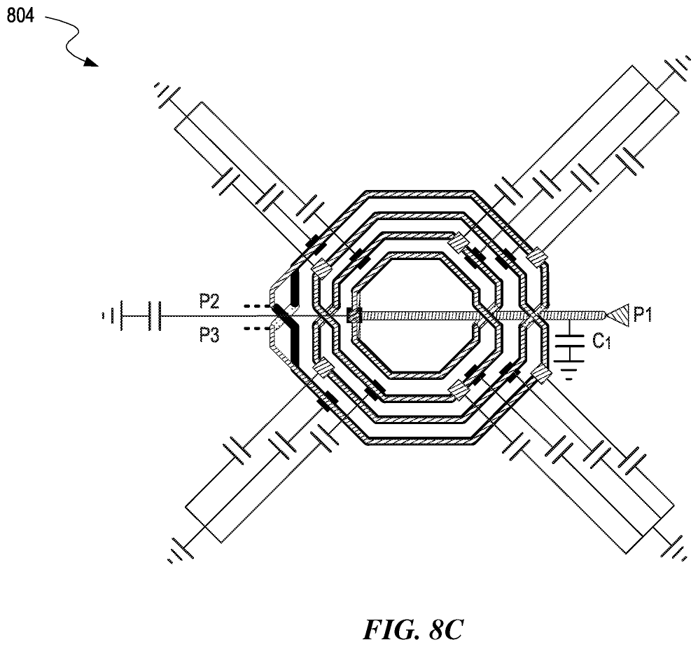

FIG. 8A shows an example partial layout 800 of a Gysel-type power divider circuit in which the isolation network is omitted. The layout 800 illustrates an implementation approach in which inductive conductors associated with multiple resonator sections are arranged in a compact, concentric polygonal footprint. In one or more embodiments, the illustrated footprint corresponds to the signal carrying portion of the Gysel-type power divider that routes signals between an input-side port P1 and output-side ports P2 and P3 through a pair of symmetric branches. Although FIG. 8A is described using power division as an example, the same topology can be used for power combining by operating the circuit in the reverse direction.

In the illustrated embodiment, the layout 800 includes conductive routing from the input-side port P1 to an interior region of the polygonal structure, and further includes conductive routing that couples from the interior region toward the output-side ports P2 and P3. A shunt capacitor C1 can be coupled at or near the input-side port P1 to a reference potential so as to provide input-side matching and/or filtering in cooperation with downstream resonator sections. By omitting the isolation network, FIG. 8A separately illustrates the placement and routing of the multi-section signal path elements that implement the impedance transforming behavior along the two branches. Thus, FIG. 8A can serve as a basis for, e.g., the isolation network introduced in FIG. 8B below.

In one or more embodiments, the concentric polygonal footprint includes a plurality of polygonal conductive loops that correspond to inductors of different resonator sections. For example, an inner polygonal loop can implement inductive conductor segments associated with an earlier resonator section, while one or more outer polygonal loops can implement inductive conductor segments associated with later resonator sections. This nested arrangement can reduce footprint and reduce interconnect length between successive sections. Further, as discussed above, the corresponding conductive features in the two branches can be placed using mirrored or otherwise symmetric geometry to reduce branch-to-branch parasitic mismatch and to support amplitude and phase balance between signals at the output-side ports P2 and P3.

FIG. 8B shows an example layout 802 illustrating coplanar inductors arranged as cascaded LC Pi elements that implement at least a portion of an isolation network for the Gysel-type power divider of FIG. 8A. In one or more embodiments, the isolation network is configured to route imbalance energy away from the signal carrying paths and toward one or more terminations referenced to a reference potential, e.g., through one or more resistive isolation loads (not shown in FIG. 8B for simplicity) that are coupled into the isolation network and that can be located off of the core signal path. In this manner, the isolation network can provide output-port isolation characteristic of a Gysel-type topology without requiring an internal isolation resistor directly between the output-side ports.

In the illustrated embodiment, the layout 802 implements a multi-section isolation network using multiple cascaded LC Pi elements. Each Pi element can include a series inductive portion between two nodes and one or more shunt capacitive portions coupled from those nodes to the reference potential. The cascaded structure can be configured to provide a frequency-dependent impedance transformation along the isolation path such that imbalance energy is coupled into the isolation network and guided toward the associated termination.

The layout 802 further shows that the inductive conductors of the isolation network can be implemented using a compact polygonal footprint and scaled by adding additional LC Pi elements in cascade. For example, the inductive conductor pattern can be laterally extended within one or more metal layers to implement additional series inductive portions, and the associated shunt capacitor connections can be integrated at selected nodes to complete additional Pi elements. Accordingly, FIG. 8B illustrates an example layout strategy for implementing at least a portion of a Gysel-type isolation network using cascaded LC Pi elements that can be integrated with the signal carrying portion of FIG. 8A.

FIG. 8C shows an example layout 804 that combines the layouts of FIGS. 8A and 8B to implement a Gysel-type power divider circuit using a hybrid footprint that includes both coplanar inductors and vertically stacked inductors. In one or more embodiments, the layout 804 integrates (1) a multi-section signal carrying network between the input-side port P1 and the output-side ports P2 and P3; and (2) an isolation network coupled toward the output-side that routes imbalance energy toward one or more terminations referenced to the reference potential.

As shown in the embodiment in FIG. 8C, multiple resonator sections and at least a portion of the isolation network can be integrated into a unified concentric polygonal footprint. For example, a subset of inductive conductors can implement series inductors for multiple resonator sections in each branch, while another subset can implement series inductors for one or more LC Pi elements of the isolation network. In accordance with the present disclosure, the geometry and placement of corresponding elements can be selected to preserve branch symmetry and to support output balance while keeping routing between successive sections short.

Moreover, the layout 804 shows that footprint reduction and scalability can be enhanced by implementing at least some inductive conductors using vertical stacking across multiple metal layers. For example, one or more inductors of the signal carrying resonator sections, one or more inductors of the isolation network, or both, can be implemented using inductive conductors on different metal layers that overlap in plan view and occupy substantially a same planar footprint, with interlayer coupling provided using vias or via regions at selected nodes. In this manner, the layout 804 can combine coplanar expansion with vertically stacked inductors so that additional resonator sections and/or additional isolation-network sections can be incorporated while preserving a compact overall footprint.

In addition, in one or more embodiments, vertical stacking can be implemented so that inductive conductors on different metal layers are magnetically coupled. For example, when two inductive conductors are vertically aligned and occupy substantially the same planar footprint, their magnetic fields can be arranged to share magnetic flux, which can in turn increase an effective inductance experienced by each stacked inductor compared to a corresponding non-stacked layout. This can enable a target inductance value (and thus a target impedance-transforming response for a resonator section and/or an isolation-network section) to be achieved with reduced planar area, thereby supporting additional sections and improved scalability while preserving a compact overall footprint.

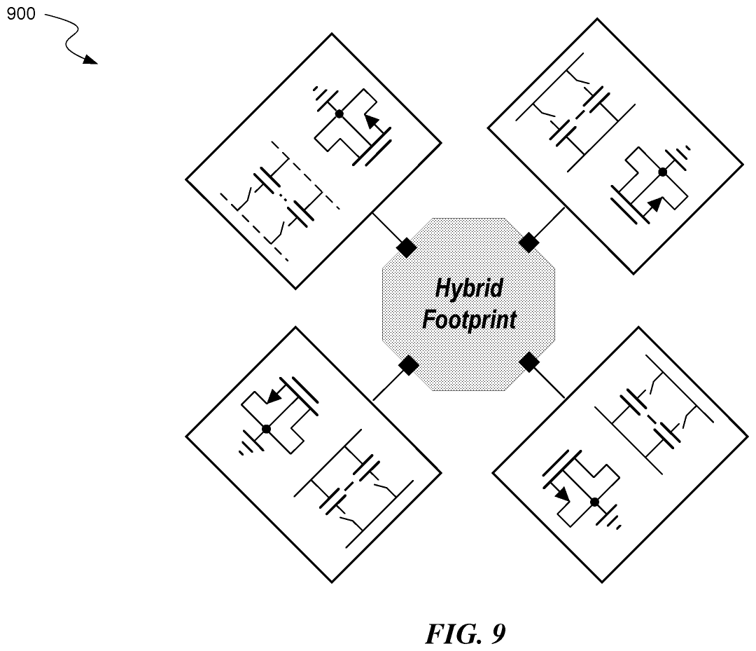

FIG. 9 shows in concept the reconfigurability of the proposed compact power divider footprint using tunable capacitance elements. In one or more embodiments, one or more capacitors in the lumped element networks described above (e.g., shunt capacitors of one or more LC Pi sections in the signal carrying portion and/or in the isolation network) can be implemented as tunable capacitors so that the impedance transforming response of the overall network can be adjusted after fabrication. In some embodiments, such tunable shunt capacitance can provide a single-footprint tap-out that allows an operational frequency shift without changing an underlying inductor-footprint geometry.

In various embodiments, the tunable capacitance can be implemented using a switched capacitor bank, a varactor, or a combination of both. For example, a switched capacitor bank can include a plurality of selectable capacitor elements that are selectively coupled into or out of the network using one or more switching devices (e.g., transistor switches), thereby providing discrete capacitance settings. In another example, a varactor can provide a continuously adjustable capacitance as a function of a control voltage. In some implementations, the tunable capacitance elements can be implemented on chip, provided as a packaged capacitor bank, or implemented using a combination of integrated and packaged components.

In one or more embodiments, tuning the capacitance values can adjust an operating frequency of the power divider circuit, adjust a bandwidth, and/or compensate for variations due to process, voltage, and temperature. For example, capacitance tuning can be used to shift a center frequency of the impedance transforming network, to flatten a response over a target band, or to calibrate output balance and isolation performance across operating conditions.

Furthermore, in some embodiments, the tunable capacitance elements are controlled by a control circuit (e.g., a bias generator and/or a digital control interface) that applies one or more control signals to select a capacitor bank state and/or to set a varactor bias. Depending on the implementation, the control circuit can implement an open loop configuration or a closed loop self-calibration.

Overall, the present disclosure provides a compact, scalable, and reconfigurable integrated implementation of lumped element T-junction-type and Gysel-type power divider and combiner circuits in which multi section LC Pi networks can be laid out using a concentric polygonal footprint. Scalability can be achieved through coplanar expansion and/or vertical stacking of inductive conductors (including stacked inductors that can share magnetic flux to increase effective inductance density). Operating characteristics such as center frequency and bandwidth can be adjusted using tunable capacitance elements such as switched capacitor banks and/or varactors.

The foregoing description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe the principles of the invention and its practical applications, thereby enabling those skilled in the relevant art to understand the claimed subject matter, the various embodiments, and the various modifications that are suited to the particular uses contemplated.

Although the Detailed Description describes certain embodiments and the best mode contemplated, the technology can be practiced in many ways no matter how detailed the Detailed Description appears. Embodiments may vary considerably in their implementation details, while still being encompassed by the specification. Particular terminology used when describing certain features or aspects of various embodiments should not be taken to imply that the terminology is being redefined herein to be restricted to any specific characteristics, features, or aspects of the technology with which that terminology is associated. In general, the terms used in the following claims should not be construed to limit the technology to the specific embodiments disclosed in the specification, unless those terms are explicitly defined herein. Accordingly, the actual scope of the technology encompasses not only the disclosed embodiments, but also all equivalent ways of practicing or implementing the embodiments.

The language used in the specification has been principally selected for readability and instructional purposes. It may not have been selected to delineate or circumscribe the subject matter. It is therefore intended that the scope of the technology be limited not by this Detailed Description, but rather by any claims that issue on an application based hereon. Accordingly, the disclosure of various embodiments is intended to be illustrative, but not limiting, of the scope of the technology as set forth in the following claims. Further, it should be noted that the various circuits disclosed herein may be described using computer-aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and VHDL; formats supporting register-level description languages like RTL; formats supporting geometry description languages such as GDSII, GDSIII, GDSIV, CIF, MEBES; and any other suitable format or language. Computer-readable media in which such formatted data and/or instructions may be embodied include, but are not limited to, non-volatile storage media in various forms (e.g., optical, magnetic, or semiconductor storage media).

What is claimed is:

1. A power divider circuit comprising:
an input port that splits into at least a transmission branch and a coupling branch;
a transmitted port positioned at an output end of the transmission branch; and
a coupled port positioned at an output end of the coupling branch,
wherein the transmission branch and the coupling branch each have a matching number of resonator sections connected in cascade, each resonator section of the transmission branch corresponding to a respective resonator section of the coupling branch,
wherein a first resonator section in the transmission branch includes a first inductor implemented as a polygonal or circular inductive conductor disposed on one or more metal layers of an integrated circuit,
wherein a first resonator section in the coupling branch includes a second inductor implemented as a polygonal or circular inductive conductor,
wherein the first inductor is primarily disposed on a first metal layer, and
wherein the second inductor is primarily disposed on a second metal layer different from the first metal layer such that the first and second inductors are vertically stacked and that each of the first and second inductors occupies substantially a same inductor footprint when viewed in plan.

2. The circuit of claim 1, wherein the first and second inductors are vertically stacked in a manner such that the first and second inductors share magnetic flux so as to increase an effective inductance for each stacked inductor.

3. The circuit of claim 1,
wherein the first inductor has a shape that is partially polygonal or circular, and
wherein the second inductor has a shape that is partially polygonal or circular and substantially complementary to the shape of the first inductor.

4. The circuit of claim 3,
wherein the shapes of the first and second inductors are substantially complementary such that, when the first and second inductors are vertically stacked and viewed in plan, the shapes of the first and second inductors together define a composite inductive conductor pattern that is substantially a complete polygonal or circular shape.

5. The circuit of claim 1, wherein the first and second inductors are symmetrical in shape when viewed in plan.

6. The circuit of claim 1, wherein the transmission branch and the coupling branch are laid out in a symmetric manner on the integrated circuit.

7. The circuit of claim 1, further comprising:
a second resonator section in the transmission branch includes a third inductor implemented as a polygonal or circular inductive conductor; and
a second resonator section in the coupling branch includes a fourth inductor implemented as a polygonal or circular inductive conductor,
wherein all of said inductors together define a composite inductive conductor pattern that exhibits two or more substantially concentric polygons.

8. The circuit of claim 7, wherein the substantially concentric polygons are octagons.

9. The circuit of claim 7, wherein each pair of corresponding inductors is symmetrical in shape.

10. The circuit of claim 1, wherein each resonator section includes an LC Pi network including a series inductor and one or more shunt capacitors.

11. The circuit of claim 1, wherein corresponding resonator sections of the transmission branch and the coupling branch are electrically symmetric so as to maintain amplitude and phase balance between the transmitted port and the coupled port.

12. The circuit of claim 1, wherein the matching number of resonator sections in the transmission branch and the coupling branch is at least two.

13. The circuit of claim 1, wherein at least one resonator section further includes a tunable capacitor configured to adjust a frequency of the power divider circuit.

14. The circuit of claim 13, wherein the tunable capacitor includes a switched capacitor bank or a varactor.

15. The circuit of claim 1, further comprising:
at least one additional resonator section in each of the transmission branch and the coupling branch that includes an inductor that is formed by coplanar expansion of an inductive conductor within a same metal layer.

16. The circuit of claim 15, wherein the coplanar expansion includes an inductive conductor that is extended laterally in an X direction and/or a Y direction of the integrated circuit.

17. The circuit of claim 1, wherein one or more of said resonator sections are implemented by laterally extending a single inductive conductor footprint to form a plurality of inductive segments arranged in a coplanar manner.

18. The circuit of claim 1, further comprising:
at least one additional resonator section in each of the transmission branch and the coupling branch that includes an inductor formed by vertical stacking of inductive conductors across multiple metal layers.

19. The circuit of claim 1, wherein the vertical stacking includes multiple inductors in one or more of said resonator sections occupying substantially the same planar footprint.

20. The circuit of claim 1,
wherein at least one resonator section includes an inductor that is formed by coplanar expansion of an inductive conductor within a same metal layer, and
wherein at least one other resonator section includes an inductor formed by vertical stacking of inductive conductors across multiple metal layers.

21. The circuit of claim 1, wherein the transmission branch and the coupling branch each include a hybrid inductive structure comprising both coplanar-expanded inductors and vertically stacked inductors.

22. The circuit of claim 1, wherein no isolation resistor is coupled between the transmitted port and the coupled port.

23. The circuit of claim 22, wherein the transmission branch and the coupling branch each include a quarter-wavelength-equivalent impedance implemented using the resonator sections connected in cascade.

24. The circuit of claim 1, further comprising:
at least two isolation loads, each isolation load being coupled between a respective branch of the power divider circuit and a reference potential.

25. The circuit of claim 24, wherein each isolation load is coupled to ground through a respective resonator section configured to route imbalance power away from the transmitted port and the coupled port.

26. The circuit of claim 24, wherein said isolation loads are external to a signal-carrying path between the input port and the transmitted and coupled ports.
